(19) United States
(12) Patent Application Publication
(10) Pub. No.: US 2024/0138044 A1
(43) Pub. Date: Apr. 25, 2024

(54) TESTING METHOD AND CONTROLLER FOR CONTROLLING TESTING METHOD

(71) Applicant: Schreder S.A., Bruxelles (BE)

(72) Inventors: Laurent Secretin, Remicourt (BE); Filipe Fernandes, Carnaxide (PT)

(21) Appl. No.: 18/546,129

(22) PCT Filed: Feb. 11, 2022
(86) PCT No.: PCT/EP2022/053426

§ 371 Date: Aug. 10, 2023

(30) Foreign Application Priority Data
Feb. 12, 2021 (NL) 2027554

(51) Int. Cl. H05B 47/20; G01J 1/44; G01R 31/44

(52) U.S. Cl. CPC H05B 47/20; G01J 1/44; G01R 31/44; G01J 2001/4247

(57) ABSTRACT

A method for testing a luminaire system, and in particular for testing whether a controller (10) of the luminaire system has been correctly installed, said controller (10) being configured to control a light source, wherein, the controller is connected through a first connection interface (11; 11a, 11b) to a driver (20), the method comprising automatically controlling by the controller (10) the following step: a) applying a light output control profile for controlling a light output of the light source during a time period, and determining at least one measure representative for the light output of the light source during said time period.

### FIELD OF INVENTION

The present invention relates to the field of luminaire testing, and in particular to a method for testing a luminaire system, and in particular for testing whether a controller, e.g. a pluggable control module, of the luminaire system has been correctly installed. The invention also relates to a controller for controlling the testing method, and to a luminaire system comprising such a controller.

### BACKGROUND

Luminaire systems comprise typically a luminaire housing in which at least one light source is arranged, the light source being driven by a driver receiving power from the mains Additionally, a controller is provided for controlling the light emitted by the light source and/or for controlling beyond-lighting devices. Typically the controller is connected to the driver. The controller may be provided in the luminaire housing. Alternatively, the controller may be provided outside of the luminaire housing, e.g. as a pluggable control module which can be plugged in a socket receptacle which is connected to the driver. Such socket receptacle may be provided e.g. on top of the luminaire housing or on a surface of the luminaire housing facing the ground. Sometimes, the controller may be integrated with the driver.

The controller receives power from the mains, either directly from the mains or from a power conversion means (e.g. included in the driver) connected to the mains, and exchanges data with the driver and/or other components of the luminaire system. The controller may be configured for performing controlling and/or sensing and/or processing and/or wireless communications. For example, the controller may be a pluggable control module with a processor and a photosensor for sensing ambient light.

Luminaire networks in urban or industrial environments may contain large numbers of luminaires Upon installation of a controller in a luminaire system or upon installation of the luminaire system, it is desirable to test whether the controller operates properly. For example, problems could be due to faulty wiring, mismatched components, and other installation issues, and it is desirable to test the operation of the controller during installation.

Historically, individuals installing simple controllers in luminaire systems such as streetlights during the daytime have tested manually the dimming operation. This may be accomplished by using one's hand to cover the photocell in order to simulate a nighttime condition to the controller. If the controller is correctly installed, the light source will be switched on shortly after the photocell is placed in this dark condition. When removing one's hand from in front of the photocell, the light source will be seen to turn off. Such a procedure requires many manual steps to be performed by an installer, is time consuming, requires a photosensor, and may not work for all types of controllers.

To address this problem, it is known to provide a controller with an integral self-test function, wherein the testing is programmed and carried out independently by the circuitry. In the event of a malfunction in the test, a warning light or an alarm alerts the user of the test malfunction. For example, the controller may be configured to trigger a test sequence when the light fixture receives a dimming test signal. In that way the user can install the light fixture and controller and test immediately once the equipment has been powered.

Although such testing methods may work well for simple controllers, for more complex controllers for example having multiple connection interfaces, the proper operation cannot be tested fully.

### SUMMARY

The object of embodiments of the invention is to provide an improved method for testing a luminaire system.

According to a first aspect of the invention, there is provided a method for testing a luminaire system, and in particular for testing whether a controller of the luminaire system has been correctly installed. The controller is configured to control a light source of the luminaire system. During installation, the controller is connected through a first connection interface to a driver for driving the light source or to the light source (in the latter embodiment a driving functionality is included in the controller), for controlling a light output emitted by the light source, and optionally through a second connection interface. The optional second interface may allow the controller to be connected to another component such as a sensor or a human interface device or a processor or a communication device. The method comprises automatically controlling by the controller the following step, upon powering the luminaire system:
a) applying a light output control profile for controlling a light output of the light source during a time period, and determining at least one measure representative for the light output of the light source during said time period.

In that way, when the luminaire system is powered, step a) will be performed automatically without requiring a manual intervention of the operator to apply the light output control profile. By having the controller automatically control the determining of at least one measure representative for the light output of the light source, an accurate testing of the good operation of the luminaire system is performed. Compared to methods where the good operation is based merely on the perception of the installer, a more reliable method is provided. Moreover, the at least one measure may be used for configuring the luminaire system and/or for other purposes.

According to an exemplary embodiment, the method further comprises after step a) automatically controlling by the controller the following step:
b) if the at least one measure does not fulfil at least one predetermined criterion, indicating a failure of the test.

In that way, a user is informed when the test indicates that the luminaire system is not working properly.

According to an exemplary embodiment, the method further comprises after step a) automatically controlling by the controller the following step:
b) if the at least one measure fulfils at least one predetermined criterion, entering a test mode to test the second connection interface; and, if the at least one predetermined criterion is not fulfilled, indicating a failure of the test.

In this way, it can be tested whether a controller having multiple connection interfaces, has been correctly installed. By entering a test mode after having performed step a), also the second connection interface may be tested during installation. Depending on the device to which the second connection interface is connected, preferably the testing of the second connection interface may be semi-automated or fully automated.

According to an exemplary embodiment, the method further comprises after step a) automatically controlling by the controller the following step:
b) if the at least one measure fulfils at least one predetermined criterion, configuring the controller and/or another component of the luminaire system based on the determined at least one measure; and, if the at least one predetermined criterion is not fulfilled, indicating a failure of the test.

In that way, any parameters or addresses or other settings linked to the light output of the light source may be configured in an improved manner right after the powering of the luminaire. This may be a configuring of the controller or of another component, such as a driver, a sensor, a human interface device, an actuator, etc.

It is noted that the two exemplary embodiments may be combined, i.e. step b may comprise both a test mode step as well as a configuring step.

Typically, determining whether the at least one predetermined criterion is fulfilled will involve determining whether the at least one measure falls within at least one range. For example, the measure may be compared with a predetermined threshold value.

The light output control profile is a profile which defines a control parameter in function of time, e.g. a dimming profile defining a dimming level in function of time; or a control profile defining a color of a light output in function of time; or a control profile defining a light pattern related parameter such as a lens position of a movable lens or a lens shape of a deformable lens, in function of time; or a light flashing/blinking pattern. More generally the control parameter may be any parameter that influences the light output. Typically, applying a light output control profile will imply that a non-zero amount of power is provided to light source. The light output control profile may be such that the power intended to be provided to the light source is non-zero during a portion of the profile and zero during another portion of the profile. The light output control profile may also be such that the power intended to be provided to the light source has a first non-zero value during a portion of the profile and a second different non-zero value during another portion of the profile. Generally, if two different power values are applied, this will typically allow to determine also the light output for other values by extrapolation.

Preferably, the light source comprises a plurality of light-emitting elements, more preferably light emitting diodes. For example, the light source may comprise a single branch comprising light emitting elements connected in series or multiple branches connected in parallel, each branch comprising one or more light emitting elements connected in series. For a tunable white light source of a light source with an adjustable color (e.g. an RGB, RGBW or RGBA light source) or a light source with any other kind of adaptive lighting, two or more channels, i.e. two or more branches of light emitting elements may be provided, each branch producing a different light output, e.g. a light output having a different color or having a different light distribution. In such an embodiment, a measure representative for the light output of each branch of the light source may be determined during said time period. For example, the light output control profile may be such that a first and second power intended to be provided to a first and second branch of a light source, such as tunable white light source, has a first and second value during a portion of the profile and a third and fourth value during another portion of the profile, said third and fourth value being different from said first and second value, respectively. For example, the first and second value could be such that a warm white is produced and the third and fourth value could be such that a cold white is produced. In such an embodiment, the at least one measure for the light output could be a first and second power consumed by the light emitting elements the first and second branch, respectively.

The powering of the luminaire system may take place in one or more steps. One or more relays may be provided to that end. Embodiments of the invention will typically be performed when at least the driver and the controller or a relevant portion thereof are powered. However, it will be understood that not all components of the luminaire system need to be powered when performing the method.

Preferably, the at least one measure comprises any one or more of the following: a measure for the power consumption such as a power value, a voltage value or a current value (e.g. measured using voltage/current/power measurement circuitry); a measure for a light intensity of the light output; a measure for a color of the light output; a measure for a light pattern of the light output. In controller where power measurement circuitry is available, it may be convenient to measure the power consumption. In addition or alternatively, in embodiments where a photocell or camera is present, it may be advantageous to measure the light intensity and/or a light color and/or light pattern.

In a preferred embodiment, the step of applying a light output control profile is configured to apply at least a first power level during a first time period and a second different power level during a second time period, and the step of determining comprises determining a first and second measure representative for a first and second light output of the light source during said first and second time period, respectively. The first and second measure may be e.g. a first and a second power consumption. The first and second period may be consecutive periods. The first time period may be before or after the second time period. Thus, in preferred embodiments at least two different constant power levels are applied. However, other embodiments may involve applying a light output control profile which increases or decreases linearly over time or a combination of one or more constant and linearly changing light output control profiles.

Preferably, the first power level corresponds with 80-100% of the maximum available power. More preferably, the first power level corresponds with 100% of the maximum available power. Preferably, the second power level corresponds with a value between 5 and 50% of the maximum available power or between 10 and 50% of the maximum available power. More preferably, the minimum dimming level is tested, which may be e.g. 5 or 10% of the maximum available power. Preferably, the first and the second time periods are each less than 30 s, preferably less than 20 s, more preferably less than 10 s. Using such power levels and time periods allows checking whether dimming works properly in a fast and automated manner Preferably, first the first power level is applied and next the second power level is applied. However, also other sequences are possible. In some cases, it may be advantageous to apply first the lower second power level and then the higher first power level, so as not to give an operator the impression that the luminaire system is not working properly. Also, more than two different power levels may be applied consecutively.

In an exemplary embodiment, the light output control profile applied during step a) is configured to switch off the luminaire system or to set it in a stand-by mode during an off-period, and to switch on the luminaire system during an on-period, and the step of determining at least one measure comprises determining a measure for the power consumption during said off-period. In that manner it can be tested whether the light source is properly switched off or put in a stand-by mode, and that no significant leakage occurs. It is noted that the off-period may be included at the beginning of the light output control profile, i.e. before the first and second period, or at the end of the light control profile, or in between the first and the second period. It is further noted that the off-period is optional, and that the first and second power level are typically sufficient to test the operation of the luminaire system.

In preferred embodiments the second connection interface is configured for being connected to a component, such as a sensor or human interface device or an actuator (such as an actuator for moving an optical element of the light source relative to a support with one or more light emitting elements) or an additional interface (i.e. not the interface used for controlling the light source) of a multi-purpose driver, in a wired manner. Alternatively, the second connection interface may be a wireless connection interface configured to receive wireless signals. The second connection interface may be e.g. a wireless communication interface or a sensing interface configured to sense signals, e.g. a sensing interface of a motion controller. In the event of a wireless communication interface, before or during step b) an installer may set-up the wireless connection, e.g. by pushing a button initiating a pairing process to set up the connection, and may next test the wireless second connection interface. Such wireless second connection interface may be used to communicate with a device of the luminaire system or with a device outside of the luminaire system such as a remote server or a mobile device of an installer.

In an exemplary embodiment, the step of determining at least one measure representative for the corresponding light output of the light source comprises measuring a power consumption using measurement circuitry provided in the controller or in the driver. For example, when the controller is a NEMA type controller, see further, the measurement circuitry for measuring the power consumption may be provided in the controller. The measurement circuitry may measure the power consumption of only the light source or the power consumption of the light source and one or more other components of the system, e.g. the controller.

In an exemplary embodiment, the step of indicating a failure of the test if the at least one predetermined criterion is not fulfilled comprises any one or more of the following: providing a visible signal to the installer, e.g. using the light source and/or an indication lamp such as an indication LED and/or a display; providing an audible signal to the installer, e.g. using a buzzer;

communicating the failure to a mobile device of the installer. Alternatively or in addition, the failure may be communicated to a remote server and/or to a mobile device of the installer. It is noted that in the test mode of step b) a predetermined light output control profile may be applied to the light source if the at least one predetermined criterion if fulfilled, and that, if this predetermined light output control profile is not applied and thus the light emitted by the light source does not correspond with this predetermined light output control profile, this may also be an indication that the test has failed. The light output control profile may be configured to output light with a certain intensity and/or color and/or light distribution in function of time.

In an exemplary embodiment, the method further comprises automatically controlling by the controller the following step: if the at least one measure fulfills the at least one predetermined criterion and/or if the second connection interface was tested successfully, indicating a success of the test and/or switching the luminaire system on. The step of indicating a success of the test if the at least one predetermined criterion is fulfilled may comprise any one or more of the above indicated signaling/communication means.

In an exemplary embodiment, during or after the test mode a result of the testing of the second connection interface is indicated to an installer. Preferably, the result is made visible via the light source. Alternatively or in addition, the result may be made visible and/or audible through another output means such as a display or a microphone. Alternatively or in addition, the result may be communicated to a remote server and/or to a mobile device of the installer.

In an exemplary embodiment, step b) comprises applying a trigger control profile for controlling a light output of the light source during a trigger period upon receipt of a trigger signal through said second connection interface. In that way the good operation of the second connection interface can be tested in a simple manner using a trigger signal.

In an exemplary embodiment, step b) comprises:
applying during a test time period a test control profile for controlling a light output of the light source if no trigger signal is received, and
applying a trigger control profile during a trigger period upon receipt of a trigger signal through said second connection interface during said test time period, said trigger control profile being configured to control, preferably to change the light output set by the test control profile; said trigger period being smaller than the test time period, preferably at least times smaller than the test time period.

In that way, the test control profile can indicate to the user that step a) was successful (i.e. the at least one measure fulfils at least one predetermined criterion), and at the same time the good operation of the second connection interface can be tested in a simple manner using a trigger signal.

In an exemplary embodiment, instead of or in addition to the step of applying during a test time period a test control profile, it may be indicated that the at least one predetermined criterion is fulfilled using any one or more of the following: providing a visible signal to the installer, e.g. using the light source and/or an indication lamp such as an indication LED and/or another light source and/or a display; providing an audible signal to the installer, e.g. using a buzzer; communicating a success message to a mobile device of the installer or to a remote server.

The test control profile may be any suitable light output control profile, e.g. a dimming profile setting a dimming level within a range from 0-100% of the maximum available power. Preferably, the test control profile is configured to apply a constant non-zero test power level to the light source, and the trigger control profile is configured to set a constant trigger power level different from the constant test power level. The test power level may be the same as the first or second power level or may be different. For example, the trigger control profile may be such that it is perceived by an installer as a blinking or flashing of the light source.

In this manner the operation of the second connection interface can be tested and the result is made visible by appropriately controlling the light source. Preferably, the test time period is longer than 5 minutes, more preferably longer than 10 minutes, or longer than 15 minutes, e.g. longer than 30 min, or even longer than 60 min. Typically, it is less than 120 minutes. The length of the test time period may be set depending on the number of luminaires to be installed in a certain area and/or on whether multiple luminaires are powered together or individually. For example, multiple luminaires mounted against the facades of houses may be connected to a single cabinet, and a single relay may be provided in the cabinet for powering the multiple luminaires simultaneously. By setting a suitable test time period, the installer has sufficient time for performing the testing of one or more second connection interfaces of one or more luminaire systems.

In an exemplary embodiment, the controller obtains a value indicative of whether it is daytime or nighttime, and, if the value indicates that it is daytime, the test control profile is configured to set to a power value between 5 and 40% of the maximum available power, and, if the value indicates that it is nighttime, the test control profile is configured to set to a power value between 60 and 100% of the maximum available power. “Daytime” and “nighttime” may be defined in any suitable manner and may e.g. correspond to a period when a measured light level is below or above a predetermined threshold. However, “daytime” and “nighttime” may also correspond with fixed time periods or may be based on other criteria than time or measured light level. Preferably, the controller comprises a photosensor, and the value indicative of whether it is daytime or nighttime is obtained using the photosensor.

Preferably, if it is determined that it is daytime, the trigger control profile is configured to set a power value which is at least 10% higher, preferably at least 20% higher, even more preferably at least 50% higher than the value set by the test control profile, and, if it is determined that it is nighttime, the trigger control profile is at least 10% lower, preferably at least 20% lower, than the value set by the test control profile, more preferably between 10% and 50% lower. Preferably, the difference is such that it is clearly visible for the installer. If the installation is performed during nighttime, preferably, the difference is clearly visible but does not cause “black spots”.

In addition or alternatively to changing the power level, the trigger control profile may cause another change of the light output, e.g. a change in color and/or a change in light distribution.

In an exemplary embodiment, the trigger signal is a signal detected by a sensor or a human interface device or an actuator connected to the second connection interface. For example, the sensor may be an environmental sensor such as a motion sensor, a pollution sensor, an image sensor such as a camera, a radar sensor, a microphone, a detector of CO₂, NOR, smoke, etc. The human interface device (HID) may be e.g. a button, such as a panic button, a touch screen, a microphone. However also other devices may be connected to the second connection interface and may be suitable for sending a trigger signal. Examples are: power management circuitry; telecommunication circuitry, such as an antenna, WiFi circuitry, repeater circuitry, e.g. a WiFi repeater, etc.; audio system management circuitry; charger circuitry, e.g. phone charger circuitry or vehicle charger circuitry; a socket, such as an electrical socket. In a preferred embodiment the trigger signal is based on a detection by a motion sensor. Such trigger signal can be easily generated by an installer by passing in front of the motion sensor. The actuator may be an actuator such as a linear motor, configured to move a portion of the light source, e.g. an optical element of the light source relative to a support with one or more light emitting elements. The trigger signal could then be a position indication.

In an exemplary embodiment, the trigger signal is a signal received through the second connection interface from a remote device. For example, the second connection interface may be connected to a receiving means configured for receiving a signal from a remote device. The remote device may be a central server or may be a mobile device which is carried by the installer.

In an exemplary embodiment, the trigger signal is a signal received through the second connection interface from a component which is configured to send one or more trigger signals upon connection to the controller. For example, the second connection interface may be connected to an output means such as a display configured for sending a trigger signal.

The trigger signal may be any kind of trigger signal, and may optionally be sent upon request of the controller.

In an exemplary embodiment, the controller is a pluggable control module. Preferably, the pluggable control module is configured to be plugged in a socket receptacle, e.g. a socket receptacle provided to a housing accommodating the light source of the luminaire system. More preferably, the socket receptacle is one of a NEMA or Zhaga socket receptacle, and the pluggable control module is a module configured to be plugged in such socket receptacle.

Examples of exemplary embodiments of control modules, pluggable control modules, socket receptacles, as well as their functionalities are disclosed in PCT publication WO 2020/161356 A1, PCT publication WO 2021/013925 A1, PCT application PCT/EP2021/061430, PCT application PCT/EP2021/071813 and NL application N2028792 in the name of the applicant, which are included herein by reference.

According to an exemplary embodiment, the socket receptacle and control module may be implemented as described in PCT publication WO2017/133793 in the name of the applicant, which is included herein by reference. Optionally, the socket receptacle and control module may be configured and/or mounted as described in patent application PCT/EP2020/068854 or PCT/EP2020/060751 in the name of the applicant, which are included herein by reference.

The socket receptacle and the control module may be configured to be coupled through a twist-lock mechanism, e.g. as described in ANSI C136.10-2017 standard or ANSI C136.41-2013 standard or Zhaga Interface Specification Standard (Book 18, Edition 1.0, July 2018, see https://www.zhagastandard.org/data/downloadables/1/0/8/1/book 18.pdf or Book 20:

Smart interface between indoor luminaires and sensing/communication modules), which are included herein by reference.

According to an exemplary embodiment, a test counter is used indicating a value representative for the number of times that step a) has been performed, and a value of the test counter is decreased after step a) has been performed. Upon a further powering of the luminaire system, step a) is only performed if the test counter is above a predetermined value.

According to an exemplary embodiment, the method comprises prior to step a), a step of detecting a dimming type and/or a protocol type (e.g. a communication or control protocol) used in the luminaire system, and the controlling by the controller of step b) is performed taking into account the detected dimming type and/or protocol type. Preferably, the step of detecting a dimming type and/or protocol type comprises detecting whether the dimming type is any one of the following: a Digital Addressable Lighting Interface DALI, such as DALI-2, D4i (DALI standard for intelligent, IoT-ready luminaires); an analogue interface such as 0-10V, 1-10V; a digital multiplex interface DMX.

According to an exemplary embodiment, the luminaire system comprises a plurality of light sources connected to a DALI bus, and the method comprises performing the step a) for said plurality of light sources.

More in particular, according to an exemplary embodiment, the luminaire system may comprise a plurality of drivers and a plurality of light sources each connected via a respective driver of said plurality of drivers to a bus, typically a DALI bus, and the method comprises performing the step a) for said plurality of light sources. The configuring in step b) may then comprise the assigning of addresses to the plurality of drivers based on the respective measures representative for the light output of the respective light sources determined in step a).

In this way the drivers may be given addresses which are logical rather than arbitrary. For example, the drivers may be given an address in function of the measured power. This will allow for a more convenient management of the drivers. For example, depending on the address, and thus depending on the power of the associated light source, a certain dimming profile may be associated to the light source.

According to an exemplary embodiment, the configuring in step b) comprises selecting a dimming profile among a plurality of dimming profiles based on the determined measure in step a).

In this way, based the determined measure for the light output, an appropriate dimming profile may be selected. For example, when multiple light sources are connected to a DALI bus, a first dimming profile may be associated to a first set of light sources thereof and a second dimming profile may be associated to a second set of light sources thereof.

According to an exemplary embodiment, the configuring in step b) comprises setting at least one dimming related configuration parameter and/or power related configuration parameter and/or or color related configuration parameter and/or light distribution related configuration parameter, e.g. in the controller, based on the determined measure in step a).

For example, if the light output control profile tries to set the dimming level at 1% but the determined measure of the light output corresponds with a dimming level of 10%, it may be derived that the minimum dimming level of the driver/light source is 10%, and this value may be stored in the controller and/or sent to a remote server.

Further, when the light output control profiles is such that two different levels are included, and a measure for the light output is determined for those two different levels, then it is possible to determine also values for the light output for other levels by extrapolation. For example, the light output control profile may comprise a portion with 100% (no dimming) and a portion with 50% dimming, and the power may be measured for 100% and 50%. Based on those values, also the expected power for any other value between 0 and 100% may be determined by extrapolation, typically linear extrapolation. Such values may be stored and used later for checking if the luminaire has a problem. For example, when the light source is faulty after a certain period of time, the measured power at a certain dimming level may be lower or higher than what was measured or derived upon installation, which is indicative of a defective luminaire system.

Also, when the light output control profile comprises a portion with 100% (no dimming) and a portion with 1% dimming, and the power measured for 100% divided by 100 is not equal to the power of 1%, it may be determined that the minimum dimming level is higher than 1%. For example, if the power for 100% is 100 W and the power for 1% is 10 W, it may be determined that the minimum dimming level is 10%. This value may define a detection limit for issue identification: if the luminaire consumption decreases below 10 W, it can be an indication of an issue, like a broken LED.

Other examples may involve determining other measures for the light output, such as color or light distribution related measures. Also, such measures may be stored for later use, e.g. to determine a defective luminaire system. For example, when three channels are present, the light output control profile could be such that the power is distributed across the channels as 80%, 10%, 10%, and the power values in the three channels may then be measured and stored or sent to a remote server for fault detection.

According to another aspect of the invention there is provided a controller configured to control a light source of a luminaire system, the controller having a first connection interface for connecting the controller to a driver for driving the light source or for connecting the controller directly to the light source (in the latter case driving circuitry may be included in the controller), and optionally a second connection interface, the controller being configured to automatically control the following step, upon powering the luminaire system:
a) applying a light output control profile for controlling a light output of the light source during a time period, and determining at least one measure representative for the light output of the light source during said time period.

According to an exemplary embodiment, the controller is configured to automatically control after step a) the following step:
b) if the at least one measure does not fulfil at least one predetermined criterion, indicating a failure of the test.

In that way, a user is informed when the test indicates that the luminaire system is not working properly.

According to an exemplary embodiment, the controller is configured to automatically control after step a) the following step:
b) if the at least one measure fulfils at least one predetermined criterion, entering a test mode to test the second connection interface; and, if the at least one predetermined criterion is not fulfilled, indicating a failure of the test.

According to an exemplary embodiment, the controller is configured to automatically control after step a) the following step:
b) if the at least one measure fulfils at least one predetermined criterion, configuring the controller and/or another component of the luminaire system based on the determined at least one measure; and, if the at least one predetermined criterion is not fulfilled, indicating a failure of the test.

Preferred and exemplary features and advantages disclosed above for embodiments of the method apply mutatis mutandis for the controller. Preferred embodiments of the controller are described in the enclosed claims.

The controller may be e.g. a control device with a light sensor as disclosed in WO 2019/081305 A1 in the name of the applicant, which is included herein by reference.

According to an exemplary embodiment, the controller is configured to control the configuring in step b) such that a dimming profile among a plurality of dimming profiles is selected based on the determined measure in step a).

According to an exemplary embodiment, the controller is configured to control the configuring in step b) such that at least one dimming related configuration parameter and/or power related configuration parameter and/or color related configuration parameter and/or light distribution related configuration parameter is set, e.g. in the controller, based on the determined measure in step a).

According to a further aspect of the invention there is provided a luminaire system comprising a light source and a controller according to any one of the embodiments disclosed above to control the light source.

According to an exemplary embodiment, the luminaire system comprises a plurality of light sources connected to a bus, typically a DALI bus, and the controller is configured to control the performing of step a) for each light source of said plurality of light sources. More in particular the system may comprise a plurality of drivers and a plurality of light sources each connected via a respective driver of said plurality of drivers to a bus, typically a DALI bus, and the controller is configured to control the performing of step a) for each light source of said plurality of light sources.

Optionally, the controller may be configured to control the configuring such that addresses are assigned to the plurality of drivers based on the respective measures representative for the light output of the respective light sources determined in step a). For example, a first driver could be a driver for lighting a road (higher power consumption) whilst a second driver could be a driver for lighting a bicycle path (lower power consumption). With logic addresses for the different types of drivers, drivers of the same type can be controlled more easily in a similar manner.

### BRIEF DESCRIPTION OF THE FIGURES

These and other aspects of the present invention will now be described in more detail, with reference to the appended drawings showing preferred embodiments of the invention. Like numbers refer to like features throughout the drawings.

FIG. 1 illustrates a schematic view of an exemplary embodiment of a luminaire system.

FIGS. 2A and 2B are schematic views of an exemplary embodiment of a luminaire system with a pluggable NEMA type control module and of a luminaire system with a pluggable Zhaga type control module, respectively.

FIG. 3 is a schematic view of an exemplary embodiment of a luminaire system with a plurality of light sources connected to a DALI bus.

FIG. 4A is a flowchart illustrating an exemplary embodiment of a first phase of a method for testing whether a NEMA type control module has been correctly installed.

FIG. 4B is a flowchart illustrating an exemplary embodiment of a first phase of a method for testing whether a Zhaga type control module has been correctly installed.

FIG. 5 is a flowchart illustrating an exemplary embodiment of a second phase of a method for testing whether a control module has been correctly installed.

FIG. 6A illustrates the light output of a luminaire system when an exemplary embodiment of the testing method is performed during daytime.

FIG. 6B illustrates the light output of a luminaire system when an exemplary embodiment of the testing method is performed during nighttime.

### DESCRIPTION OF EMBODIMENTS

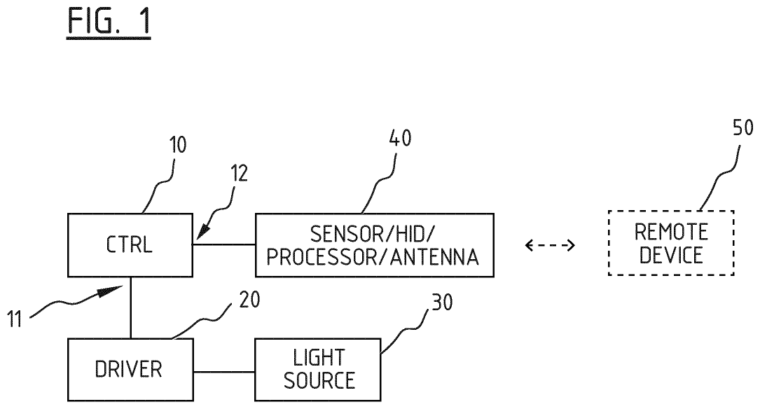

FIG. 1 shows a luminaire system comprising a light source 30, a driver 20 configured for driving the light source 30, and a controller 10 configured to control the light source 30. The controller 10 has a first connection interface 11 for connecting the controller 10 to the driver 20, and a second connection interface 12 for connecting the controller 10 to another component 40 such as a sensor, a human interface device, a processor, an antenna, etc. In another non-illustrated example the second connection interface 12 may be another interface connected to the driver 20, e.g. when the driver is a multipurpose driver performing also other tasks apart from driving the light source 30. Optionally the other component 40 and/or the controller 10 may be configured to communicate with a remote device 50, such as a central server or a fog device or a mobile device of an operator.

Preferably, the second connection interface 12 is configured for being connected to the component 40 in a wired manner. Alternatively, the connection interface 12 may be a wireless connection interface configured to receive and/or emit wireless signals.

The controller 10 receives power from the mains, either directly from the mains or from a power conversion means (e.g. included in the driver) connected to the mains, and exchanges data with the driver and/or other components of the luminaire system. The controller 10 may be configured for performing controlling and/or sensing and/or processing and/or wireless communications. For example, the controller 10 may be a pluggable control module with a processor and a photosensor for sensing ambient light.

In some embodiments the driver 20 or a portion of the driver 20 may be included in the controller 10, so that the control and drive circuitry are included in a single device. In that case the controller can be directly connected to the light source 30 through the first connection interface 11.

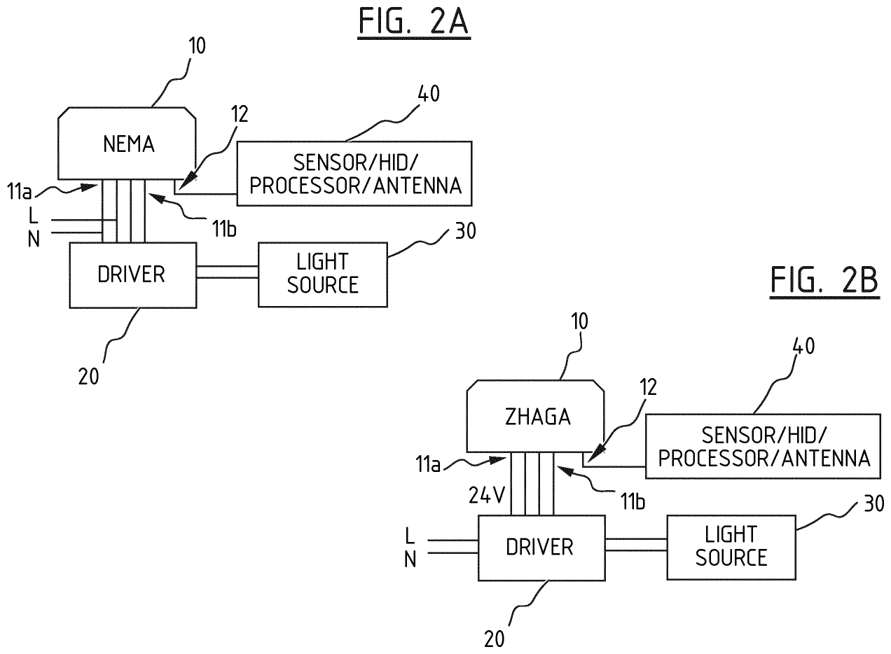

FIGS. 2A and 2B illustrate two exemplary embodiments of a luminaire system with a controller 10 being a pluggable module. The same or similar components have been indicated with the same reference numerals as in FIG. 1 and will not be described again. In the example of FIG. 2A the controller is a NEMA control module and in the example of FIG. 2B the controller is a Zhaga control module. The socket receptacle (not shown) in which the control module is plugged may then also be of a NEMA or a Zhaga type, respectively. Preferably, the requirements of the ANSI C136.41-2013 standard or the ANSI C136.10-2017 standard are fulfilled for the NEMA control module, and the requirements of the Zhaga standard (Book 18, Edition 1.0, July 2018, see https://www.zhagastandard.org/data/downloadables/1/0/8/1/book 18.pdf or Book 20:

Smart interface between indoor luminaires and sensing/communication modules) are fulfilled for the Zhaga control module.

In the example of FIG. 2A the control module 10 receives power directly from the mains L, N. The driver 20 also receives power directly from the mains L, N. The first connection interface comprises here at least two power connections 11a for receiving a power signal from the mains L, N, and two control connections 11b for communicating a control dimming signal from the control module 10 to the driver 20.

In the example of FIG. 2B the control module 10 receives power, e.g. a DC power signal such as 24V DC signal, from a power conversion means included in the driver 20. The driver 20 is connected to the mains L, N. The first connection interface comprises here at least two power connections 11a for receiving a DC power signal from the driver 20, and one or more control connections 11b for communicating a light output control signal from the control module 10 to the driver 20.

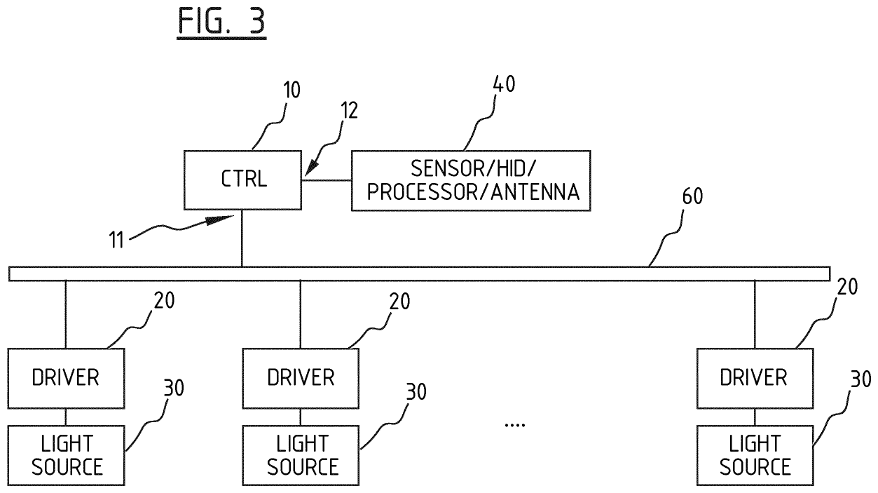

FIG. 3 illustrates an exemplary embodiment of a luminaire system comprising a plurality of drivers and a plurality of light sources 30 connected to a DALI bus 60. The luminaire system further comprises a controller 10 configured to control the light output of the plurality of light sources 30. The controller 10 has a first connection interface 11 connected to the DALI bus 60, and a second connection interface 12 for connecting the controller 10 to another component 40 such as a sensor, a human interface device, a processor, and antenna, etc.

In the examples of FIGS. 1, 2A, 2B and 3, the controller 10 is configured to automatically control the following steps, upon powering the luminaire system:
a) applying a light output control profile for controlling a light output of the light source during a time period, and determining at least one measure representative for the light output of the light source 30 during said time period;
b) if the at least one measure fulfils at least one predetermined criterion, entering a test mode to test the second connection interface 12 of the controller; and/or configuring the controller 10 and/or another component of the luminaire system based on the determined at least one measure; and, if the at least one predetermined criterion is not fulfilled, indicating a failure of the test.

In the examples of FIGS. 1, 2A, 2B and 3, the controller 10 and/or the driver 20 may comprise measurement circuitry configured for determining the at least one measure representative for the power consumption of the light source. In addition or alternatively, the at least one measure may comprise any one or more of the following: a measure for a light intensity of the light output, a measure for a color of the light output, a measure for a light pattern of the light output.

In FIG. 3 the controller 10 may be configured to control the performing of step a) for each light source of said plurality of light sources. Optionally, the controller 10 may be configured to control the configuring such that addresses are assigned to the plurality of drivers 20 based on the respective measures representative for the light output of the respective light sources determined in step a). In other words, based on a measure of the light output, e.g. the power, of a first light source 30, an appropriate address may be chosen for the driver 20 associated with the first light source 30. For example, all light sources 30 with a similar light output may be given consecutive addresses. This facilitates the further controlling and configuring of the drivers 20.

According to an exemplary embodiment, the controller 10 is configured to control the configuring in step b) such that a dimming profile among a plurality of dimming profiles is selected based on the determined measure in step a) and/or such that at least one dimming related configuration parameter and/or power related configuration parameter and/or color related configuration parameter and/or light distribution related configuration parameter is set, e.g. in the controller, based on the determined measure in step a). For example, as explained in the summary, the determined measures for the light output may be stored and/or used to determine certain parameters that are useful for checking the good operation of the luminaire system during normal operation. For example, such measures and/or parameters may be compared with measurements performed during normal operation in order to check if the operation of the luminaire system is still good.

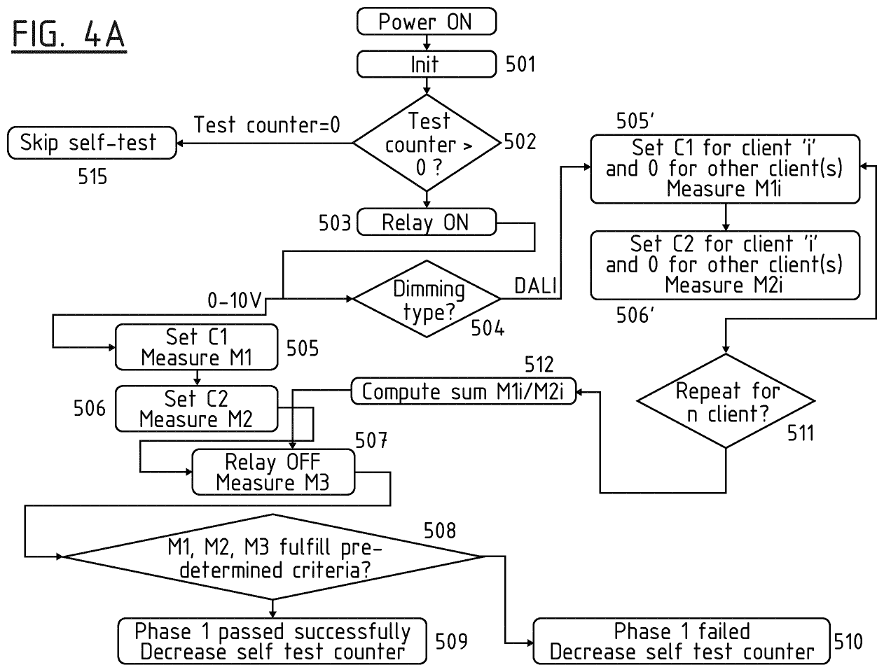

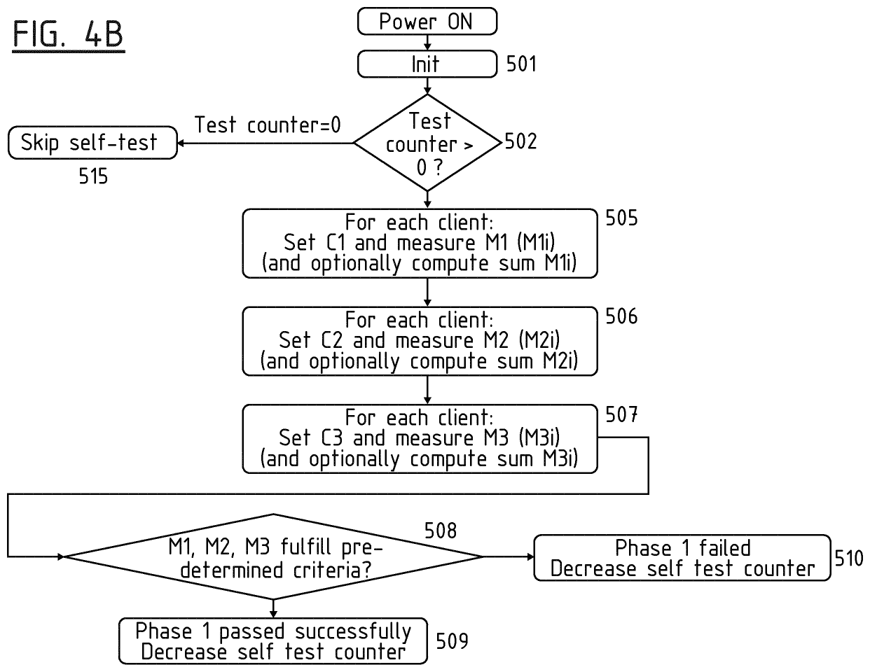

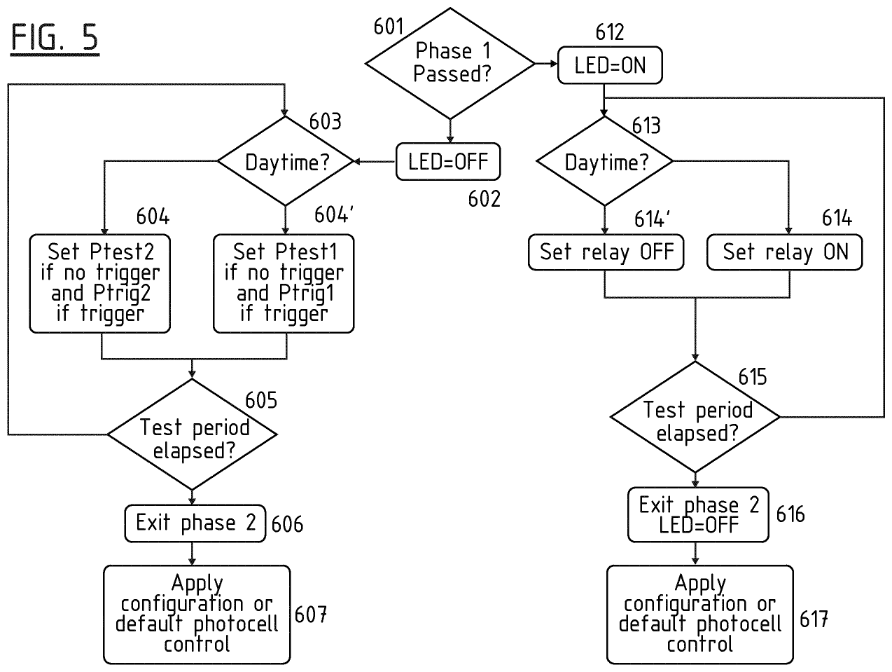

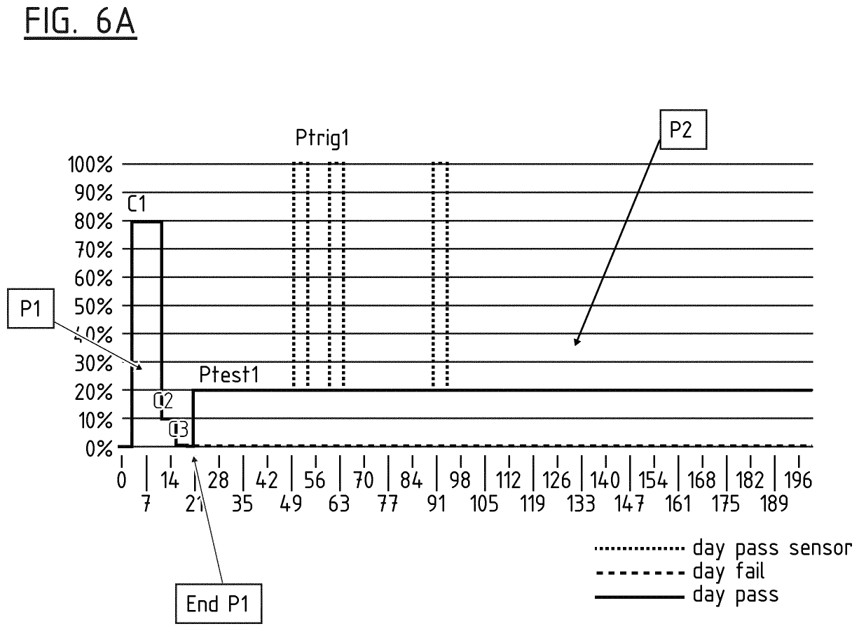

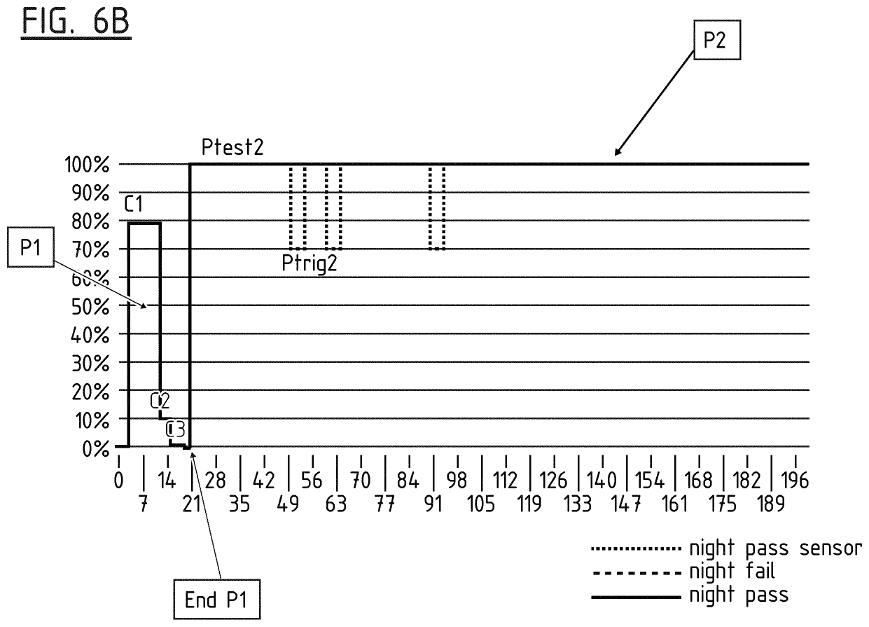

A more detailed explanation of possible implementations of the steps controlled by the controller 10 will now be described with reference to FIGS. 4A, 4B, 5, 6A, 6B. FIGS. 4A and 4B illustrate an exemplary embodiment of step a), also called phase 1, for a NEMA type control module and a Zhaga type control module, respectively. FIG. 5 illustrates an exemplary embodiment of step b), also called phase 2. FIGS. 6A and 6B illustrate exemplary dimming levels during phase 1 and 2, for an installation during daytime and nighttime, respectively.

The controller 10 is configured to control a self-test sequence. Prior to executing the self-test sequence, typically the following may have been done:
initialization of one or more configuration variables of the controller, e.g. initialization of Lightweight machine-to-machine, LWM2M object(s) and resource(s).
identification of a dimming type, if the dimming type is not known. For example, the controller 10 may be configured to control, prior to step a), a step of detecting a dimming type used in the luminaire system, and to perform the dimming taking into account the detected dimming type, wherein preferably the step of detecting a dimming type comprises detecting whether the dimming type is any one of the following: a Digital Addressable Lighting Interface DALI, such as DALI-2, D4i; an analogue interface such as 0-10V, 1-10V; a digital multiplex interface DMX.
in case of a DALI (such as DALI2 or D4i) dimming type, the number of DALI client(s) may be identified and each DALI client(s) may be commissioned.
in case of a NEMA type control module, cf. FIG. 2A, it is checked if the power relay in the controller is set in an OFF state.
in case of a NEMA type control module with a sensor, the sensor input is ignored during this stage.

The controller 10 may be configured to use a test counter indicating a value representative for the number of times that step a) has been performed, and the controller may be configured to decrease a value of the test counter after step a) has been performed. Preferably, as illustrated in step 501 and 502 of FIGS. 4A and 4B, upon powering of the luminaire system, first, as explained above, an initialization of the controller is performed. Next it is checked if the test counter is above a predetermined value, here a value 0. If the test counter is 0, the self-test is not performed, see step 515. The test counter is used to ensure the routine will occur during an installation phase to provide feedback to the installer, without compromising the power-ON behavior under regular operation. The self-test routine is executed at power-ON as long as a self-test counter is >0, allowing the installer, after switching on the entire road, to go to each pole and toggle the fuse in order to re-trigger the routine and to observe that it is executed. For example, a default value of the self-test counter could be 5, as five instances allow the installer to do troubleshooting if dimming or the second connection interface are not working at first trial. Each time step a), which corresponds with a self-test “phase 1” in the description below, is completed, then the test counter shall be decreased by one unit regardless of whether the device is registered/configured or not, see steps 509 and 510 in FIGS. 4A and 4B. When the controller gets registered/configured then a remote device, e.g. the cloud or a mobile device of an operator, can push the test counter value down to 0 to prevent the controller to perform a self-test at next power cycles. The remote device may also push back a higher value in the test counter to force the controller to perform again a self-test if needed.

The purpose of step a), i.e. of phase 1 illustrated in FIGS. 4A and 4B, is to check proper ability to dim the light source(s) (including each DALI driver in case of multi-DALI system as illustrated in FIG. 3) and proper ability to switch it OFF (NEMA, FIG. 4A) or to put it in stand-by mode (D4i, FIG. 4B).

Assuming the self-test counter is above 0, the next step 505, 505′ of phase 1 consists of measuring a measure M1 for a light output of the light source, e.g. the power consumption of the light source (or consecutively a measure M1i for the light output of each client of the luminaire system in an embodiment as illustrated in FIG. 3) at a first light output control value C1, e.g. intended to provide a first power level, e.g. a maximum power level or between 60 and 100% of the maximum power level. In case of multiple clients, then the total measure for the light outputs, e.g. the total power consumption can be computed by adding individual measures M1i, e.g. the individual power consumptions of each client, see steps 511 and 512 in FIG. 4A. It is further noted that in case of multiple clients, it is preferred to control one client at a time, i.e. when the first control value C1 is set for the first client to cause a non-zero light output at the first client, the other clients are controlled such that they do not generate a light output.

A further step 506, 506′ consists of measuring a measure M2 for a light output of the light source, e.g. the power consumption of the light source (or consecutively a measure M2i for the light output of each client of the luminaire system in an embodiment as illustrated in FIG. 3) at a second light output control value C2, e.g. a minimum dimming level, e.g. 5% or 10% of the maximum power level.

Thus, in this exemplary embodiment, the step of applying a light output control profile may comprise applying at least a first light output control value C1 resulting in a first power level, e.g. the maximum power level, during a first time period and a second light output control value C2 resulting in a second different power level, e.g. the minimum dimming level, during a second time period, and the step of determining comprises determining a first and second measure M1, M2 representative for the first and second light output of the light source during said first and second time period, respectively, e.g. a first and second power consumption value. It is noted that in other embodiments, instead of setting e.g. the maximum power level and a minimum dimming level, a different light output control profile could be used, e.g. a light output control profile configured to linearly decrease the power from a maximum power level to the minimum dimming level or a profile configured to cause a sequence of different power levels between 0% and 100%, or a profile configured to generate different colors and/or different light distributions.

In the example of FIG. 4A where the control module is a NEMA type control module, a further step 507 may comprise switching off the light source (“Relay in controller OFF”, FIG. 4A) or setting it up in stand-by mode (FIG. 4B), and measuring a further measure M3, e.g. the total Power OFF consumption.

Thus, in this exemplary embodiment, the light output control profile applied during step a) is configured to cause during an off-period a switching off of the light source or setting it in a stand-by mode and the step of determining at least one measure may comprise determining a measure for the power consumption during said off-period.

In step 508 the controller performs the following checks to define if phase 1 passed successfully or failed. To that end the controller checks if the measures M1, M2, M3 fulfils certain predetermined criteria, e.g.:
check that the first measure M1 or the sum of the first measures M1i (in case of multiple clients) is larger than a predetermined first threshold, e.g. check if the first power consumption or the total first power consumption at maximum level is >10 W
check that the second measure M2 or the sum of the first measures M2i (in case of multiple clients) is within a predetermined range, e.g. check if the second power consumption or the total second power consumption (in case of multiple DALI clients) at minimum dimming level is at least twice higher than the total power consumption in the OFF state; and does not exceed 75% of the total power consumption of the light source at maximum level.
check that the third measure M3 or the sum of the second measures M3i (in case of multiple clients) is lower than a predetermined third threshold, e.g. check if the third power consumption or the total third power consumption when the light source is in stand-by or OFF is <5 W

At the end of phase 1 the self-test counter is decreased by one unit, see steps 509 and 510.

The purpose of phase 2 (step b)) is to test the second connection interface, e.g. connected to a sensor, and to provide a feedback, e.g. a visual feedback to the installer using the luminaire light output, to report the outcome of phase 1 and/or phase 2.

In this exemplary embodiment illustrated in FIG. 5, phase 2 comprises, see steps 604, 604′:
applying during a test time period a test control profile Ptest if no trigger signal is received, e.g. a test control profile configured to generate a constant light output, and
applying a the trigger control profile Ptrig during a trigger period upon receipt of a trigger signal through said second connection interface during said test time period, said trigger control profile being configured to change the light output set by the test control profile; said trigger period being preferably at least 10 times smaller than the test time period.

Preferably the test time period is longer than 5 min, more preferably longer than 10 min, e.g. 120 minutes.

In the illustrated example, during phase 2, the light output of the light source depends on the outcome of phase 1, whether it is daytime or nighttime, and whether the second connection interface operates properly. The operation during phase 2 may be identical for a NEMA or Zhaga type controller.

In a first step 601, it is determined whether or not phase 1 was successful, see also steps 508, 509 and 510 of FIGS. 4A and 4B. If phase 1 was successful a warning LED is switched off in step 602. If phase 1 was not successful a warning LED is switched on in step 612. This is an optional step.

If phase 1 was successful, in step 603 it is checked, e.g. using a photocell of the controller, whether it is daytime or nighttime. If it is daytime, then in step 604′ the test control profile Ptest1 may be a first dimming profile which sets a first constant dimming level, e.g. 20%, when no trigger signal is received at the second connection interface. When a trigger signal is received, a first trigger test profile Ptrig1 may be set, e.g. another constant dimming profile causing the power level to be changed e.g. to 100% during a trigger time period of e.g. 2 s, see FIG. 6A. If it is nighttime, then in step 604 test control profile Ptest2 may be a second constant dimming profile, e.g. setting the power level at 100% when no trigger signal is received at the second connection interface. When a trigger signal is received, a second trigger test profile may be set, e.g. another constant dimming profile causing the power level to be changed e.g. to 70% with a trigger time period of e.g. 2s, see FIG. 6B. As long as the test time period has not lapsed, steps 603, 604 or 604′, 605 may be repeated. Thus, if during phase 2 there is a switch from day- to nighttime or vice versa, the controller can immediately change to an appropriate power level, see steps 604 and 604′. After the test time period has lapsed, e.g. after 120 minutes, phase 2 is finished, see step 606 and the controller may enter in a normal operation mode, see step 607.

Thus, in the illustrated example, the controller is configured for obtaining a value indicative of whether it is daytime or nighttime, and, if the value indicates that it is daytime, the test control profile may be configured to set to a power value between 5 and 40% of the maximum available power, and, if the value indicates that it is nighttime, the test light output control profile may be configured to set to a power value between 60 and 100% of the maximum available power. Preferably, the controller comprises a photosensor, and the value indicative of whether it is daytime or nighttime is obtained using the photosensor.

If phase 1 was not successful, in step 613 it is checked, e.g. using a photocell of the controller, whether it is daytime or nighttime. If it is daytime, then in step 614′, the relay is OFF corresponding with a power level of 0%. If it is nighttime, then in step 614, the relay is ON and e.g. a power level of 100% may be provided. As long as the test time period has not lapsed, steps 613, 614 or 614′, 615 may be repeated. After the test time period has lapsed, phase 2 is finished and the warning LED may be switched off, see step 616 and the controller may enter in a normal operation mode, see step 617.

As a consequence, during daytime the light source is used to provide a feedback to the installer. A light source that is ON during phase 2 indicates a luminaire system that passed the self-test phase 1 successfully. Then the installer can test the second connection interface during phase 2, e.g. by testing sensor trigger capability in case the second connection interface is connected to a sensor. If a luminaire is OFF during phase 2 (see step 614′) then this is a luminaire that failed self-test phase 1. During night time usually it is preferred to switch the light source ON whatever the outcome of phase 1 for safety reasons (see step 614). Then only the warning LED of the controller may be used to provide a feedback to the installer.

When the second connection interface is connected to a sensor, during phase 2, the light level is changing when the sensor connected to the controller is triggered within the test time period. Optionally, a counter is increased each time the sensor input is triggered so that the total number of sensor triggering over phase 2 can be retrieved from the cloud.

Whilst the principles of the invention have been set out above in connection with specific embodiments, it is understood that this description is merely made by way of example and not as a limitation of the scope of protection which is determined by the appended claims.

1-45. (canceled)

46. A method for testing a luminaire system, and in particular for testing whether a controller of the luminaire system has been correctly installed, said controller being configured to control a light source of the luminaire system, wherein, during installation, the controller is connected through a first connection interface to a driver for driving the light source or to the light source, for controlling a light level emitted by the light source, the method comprising automatically controlling by the controller the following step, upon powering the luminaire system:
a) applying a light output control profile for controlling a light output of the light source during a time period, and determining at least one measure representative for the light output of the light source during said time period.

47. The method of claim 46, wherein the method further comprises after step a) automatically controlling by the controller the following step:
if the at least one measure does not fulfil at least one predetermined criterion, indicating a failure of the test.

48. The method of claim 46, wherein the method further comprises automatically controlling by the controller the following step:
b) if the at least one measure fulfils at least one predetermined criterion,
entering a test mode to test a second connection interface of the controller; and/or
configuring the controller and/or another component of the luminaire system based on the determined at least one measure.

49. The method of claim 46, wherein the at least one measure comprises any one or more of the following: a measure for the power consumption such as a power value, a voltage value or a current value, a measure for a light intensity of the light output, a measure for a color of the light output, or a measure for a light pattern of the light output, and/or
wherein the step of applying a light output control profile is configured to apply at least a first power level during a first time period and a second different power level during a second time period, wherein the step of determining comprises determining a first and second measure representative for a first and second light output of the light source during said first and second time period, respectively, wherein preferably the first power level corresponds with 80-100% of the maximum available power, and/or wherein preferably the second power level corresponds with a value between 5 and 50% of the maximum available power, and/or wherein preferably the first and the second time period are each less than 30 s, preferably less than 20 s.

50. The method of claim 48, wherein during or after the test mode a result of the testing of the second connection interface is indicated to an installer, and wherein optionally the indicating comprises any one or more of the following: providing a visible signal to the installer, e.g. using an indication lamp or a display; or providing an audible signal to the installer.

51. The method of claim 46, wherein the step of determining at least one measure representative for the light output of the light source comprises measuring a power consumption using measurement circuitry provided in the controller or in the driver.

52. The method of claim 47, wherein the step of indicating a failure of the test if the at least one predetermined criterion is not fulfilled comprises any one or more of the following:
providing a visible signal to the installer, e.g. using an indication lamp or a display; or
providing an audible signal to the installer, communicating the failure to a remote server and/or to a mobile device of the installer.

53. The method of claim 48, wherein step b) comprises applying a trigger control profile for controlling a light output of the light source during a trigger period upon receipt of a trigger signal through said second connection interface.

54. The method of claim 48, wherein step b) comprises:
applying during a test time period a test control profile for controlling a light output of the light source if no trigger signal is received through the second connection interface; and
applying a trigger control profile during a trigger period upon receipt of a trigger signal through said second connection interface during said test time period, said trigger control profile being configured to control, and preferably to change the light output set by the test control profile, said trigger period being preferably at least 10 times smaller than the test time period,
wherein preferably said test control profile is configured to apply a constant test power level to the light source, wherein said trigger control profile is configured to apply a constant trigger power level different from the constant test power level to the light source, and
wherein preferably the test time period is longer than 5 minutes, preferably longer than 10 min, more preferably longer than 15 min.

55. The method of claim 54, further comprising obtaining a value indicative of whether it is daytime or nighttime, wherein, if the value indicates that it is daytime, the test control profile is configured to set a power value between 5 and 40% of the maximum available power, wherein, if the value indicates that it is nighttime, the test control profile is configured to set a power value between 60 and 100% of the maximum available power,
wherein preferably, if it is determined that it is daytime, the trigger control profile is configured to set a power value which is at least 10% higher, preferably at least 20% higher, than the power value set by the test control profile, and wherein, if it is determined that it is nighttime, the trigger control profile is configured to set a power value which is at least 10% lower, preferably at least 20% lower, than the power value set by the test control profile,
wherein preferably the controller comprises a photosensor, and wherein the value indicative of whether it is daytime or nighttime is obtained using the photosensor.

56. The method of claim 54, wherein the trigger signal is a signal detected by a sensor or a human interface device or a communication device connected to the second connection interface, and/or
wherein the trigger signal is a signal received through the second connection interface from a remote device.

57. The method of claim 46, wherein the light output control profile applied during step a) is configured to switch off the luminaire system or to set it in a stand-by mode during an off-period, and to switch on the luminaire system during an on-period, and the step of determining at least one measure comprises determining a measure for the power consumption during said off-period, and/or
wherein a test counter is used indicating a value representative for the number of times that step a) has been performed, wherein a value of the test counter is decreased after step a) has been performed, and wherein, upon a further powering of the luminaire system, step a) is only performed if the test counter is above a predetermined value, and/or
wherein the method further comprises prior to step a), a step of detecting a dimming type and/or a protocol type used in the luminaire system, wherein preferably the controlling by the controller of step b) is performed taking into account the detected dimming type and/or the detected protocol type, and wherein preferably the step of detecting a dimming and/or protocol type comprises detecting whether the dimming type is any one of the following: a Digital Addressable Lighting Interface DALI, such as DALI-2, D4i; an analogue interface such as 0-10V, 1-10V; or a digital multiplex interface DMX, and/or
wherein the controller is a pluggable control module, and/or
wherein the luminaire system comprises a plurality of drivers and a plurality of light sources each connected via a respective driver of said plurality of drivers to a bus, typically a DALI bus, and wherein the method comprises performing the step a) for said plurality of light sources.

58. The method of claim 48, wherein the luminaire system comprises a plurality of drivers and a plurality of light sources each connected via a respective driver of said plurality of drivers to a bus, typically a DALI bus, and wherein the method comprises performing the step a) for said plurality of light sources and the configuring in step b) comprises assigning of addresses to the plurality of drivers based on the respective measures representative for the light output of the respective light sources determined in step a), and/or
wherein the configuring in step b) comprises selecting a dimming profile among a plurality of dimming profiles based on the determined measure in step a), and/or
wherein the configuring in step b) comprises setting at least one dimming related configuration parameter and/or power related configuration parameter and/or color related configuration parameter and/or light distribution related configuration parameter, e.g. in the controller or in the driver, based on the determined measure in step a).

59. A controller configured to control a light source of a luminaire system, the controller having a first connection interface for connecting the controller to a driver for driving the light source or directly to the light source, the controller being configured to automatically control the following step, upon powering the luminaire system:
a) applying a light output control profile for controlling a light output of the light source during a time period, and determining at least one measure representative for the light output of the light source during said time period,
wherein preferably the controller being configured to automatically control the following step after step a):
if the at least one measure does not fulfil at least one predetermined criterion, indicating a failure of the test.

60. The controller of claim 59, the controller being configured to automatically control the following step after step a):
b) if the at least one measure fulfils at least one predetermined criterion,
entering a test mode to test a second connection interface of the controller; and/or
configuring the controller and/or another component of the luminaire system based on the determined at least one measure.

61. The controller of claim 59, wherein the light output control profile is configured to apply at least a first power level during a first time period and a second different power level during a second time period, wherein the step of determining comprises determining a first and second measure representative for the first and second light output of the light source during said first and second time period, respectively, and wherein the first power level preferably corresponds with 80-100% of the maximum available power, and/or wherein the second power level preferably corresponds with a value between 5 and 50% of the maximum available power, wherein preferably the first and the second time period are each less than 30 s, preferably less than 20 s, and/or
wherein the light output control profile applied during step a) is configured to switch off the luminaire system or to set it in a stand-by mode during an off-period, and to switch on the luminaire system during an on-period, and the step of determining at least one measure comprises determining a measure for the power consumption during said off-period.

62. The controller of claim 60, wherein the controller is configured to control the light source or another output device such that during or after the test mode a result of the testing of the second connection interface is communicated to an installer, and/or
wherein step b) comprises
applying during a test time period a test control profile for controlling a light output of the light source if no trigger signal is received through the second connection interface, and
applying a trigger control profile during a trigger period upon receipt of a trigger signal through said second connection interface during said test time period, said trigger control profile being configured to change the light output set by the test control profile, said trigger period being preferably at least 10 times smaller than the test time period, wherein preferably the test time period is longer than 5 min, preferably longer than 10 min, wherein preferably the controller is configured for obtaining a value indicative of whether it is daytime or nighttime, wherein, if the value indicates that it is daytime, the test control profile is configured to set to a power value between 5 and 40% of the maximum available power, wherein, if the value indicates that it is nighttime, the test control profile is configured to set to a power value between 60 and 100% of the maximum available power, wherein optionally the controller comprises a photosensor, and wherein the value indicative of whether it is daytime or nighttime is obtained using the photosensor.

63. The controller of claim 59, wherein the controller is a pluggable control module, and/or
wherein the controller is configured to use a test counter indicating a value representative for the number of times that step a) has been performed, and wherein the controller is configured to decrease a value of the test counter after step a) has been performed, and wherein the controller is configured such that, upon a second powering of the luminaire system, step a) is only performed if the test counter is above a predetermined value, and/or
wherein the controller is configured to control, prior to step a), a step of detecting a dimming type and/or a protocol type used in the luminaire system, and wherein preferably the controller is configured to perform the controlling of step b) taking into account the detected dimming type and/or protocol type.

64. The controller of claim 60, wherein the controller is configured to control the configuring in step b) such that a dimming profile among a plurality of dimming profiles is selected based on the determined measure in step a), and/or
wherein the controller is configured to control the configuring in step b) such that at least one dimming related configuration parameter and/or power related configuration parameter and/or color related configuration parameter and/or light distribution related configuration parameter is set, e.g. in the controller, based on the determined measure in step a).

65. A luminaire system comprising a light source and a controller according to claim 59 to control the light source, wherein preferably the luminaire system comprises a plurality of drivers and a plurality of light sources each connected via a respective driver of said plurality of drivers to a bus, typically a DALI bus, wherein the controller is configured to control the performing of step a) for each light source of said plurality of light sources, and wherein preferably the controller is configured to control the configuring such that addresses are assigned to the plurality of drivers based on the respective measures representative for the light output of the respective light sources determined in step a).
